(19) United States
(12) Patent Application Publication
(10) Pub. No.: US 2022/0077310 A1
(43) Pub. Date: Mar. 10, 2022

(54) METHOD OF MANUFACTURING A DOPED AREA OF A MICROELECTRONIC DEVICE

(71) Applicant: COMMISSARIAT A L'ENERGIE ATOMIQUE ET AUX ENERGIES ALTERNATIVES, Paris (FR)

(72) Inventors: Shay REBOH, Grenoble Cedex 09 (FR); Jean-Pierre COLINGE, Carmichael, CA (US)

(73) Assignee: COMMISSARIAT A L'ENERGIE ATOMIQUE ET AUX ENERGIES ALTERNATIVES, Paris (FR)

(21) Appl. No.: 17/447,339

(22) Filed: Sep. 10, 2021

(30) Foreign Application Priority Data
Sep. 10, 2020 (FR) 20 09167

(51) Int. Cl. H01L 29/78; H01L 29/08; H01L 29/66; H01L 29/417

(52) U.S. Cl. CPC H01L 29/785; H01L 29/0843; H01L 29/66553; H01L 29/41775; H01L 29/66795

(57) ABSTRACT

A method for forming a source/drain region of a transistor includes providing a substrate carrying a transistor pattern, comprising a base portion having an upper face elongated along an axis, a channel surmounting the base portion, and a spacer transversely surrounding a lateral portion of the channel, forming a protective layer on a facet of the channel, so as to prevent an oxidation of the lateral portion of the channel, forming an additional insulation portion in the base portion, by oxidation from the upper face, removing the protective layer so as to expose the facet, and forming by lateral epitaxy, the source/drain region from said facet.

### TECHNICAL FIELD

The present invention relates to the field of microelectronics. It finds a particularly advantageous application in the production of sources and drains in transistors requiring low thermal budgets, in particular in the field of monolithic 3D integration.

### STATE OF THE ART

In the semiconductor industry, a diversification of transistor architectures has emerged in order to meet the technological nodes defined by the International Technology Roadmap for Semiconductors (ITRS).

The FinFET transistor architectures have shown a great potential to further increase the transistor performance according to the ITRS. Other architectures, such as the gate-all-around GAA transistors or nanowire-based transistors NWFET, have also shown promising levels of performance.

FIGS. 1A-1D illustrate a portion of the steps of a method for manufacturing a FinFET transistor, according to the prior art. As illustrated in FIG. 1A, a fin 13 is formed on a substrate 1. This fin 13 surmounts a base portion 10 of the substrate 1. This base portion 10 is typically made of a semiconductor material. The substrate 1 also comprises insulation portions 11, 12 located on either side of the base portion 10. The fin 13 and the base portion 10 extend mainly along a longitudinal axis x. As illustrated in FIG. 1B, the fin 13 is structured so as to form a channel 20 comprising a central portion 200 and lateral portions 210, 220. A transistor gate pattern 3 is formed around the central portion 200 of the channel 20. Spacers 4 are also formed on either side of the gate pattern 3 and surround the lateral portions 210, 220 of the channel 20. An etching is performed so as to expose a facet 211a, 221a for each lateral portion 210, 220 of the channel 20. A transistor pattern 2 comprising the gate pattern 3, the spacers 4, and the central 200 and lateral 210, 220 portions of the channel 20, is thus obtained on the substrate 1. The source and drain regions 51, 52 of the transistor are then formed by epitaxy from the portion of the upper face 100 of the base portion 10 of the substrate 1 and on the exposed facets 211a, 221a of the channel 20, as illustrated in FIG. 1C. Contacts 61, 62 can then be deposited on the source and drain regions 51, 52 of the FinFET transistor(s) (FIG. 1D).

For the FinFET architectures, and similarly for GAA or NWFET architectures, the leakage currents and the access resistance at the contact are nevertheless significant issues. The leakage currents occur in particular from the source and drain regions to the substrate. One solution consists in forming a barrier region, typically by counter-doping, under the source and drain regions in the base portion. This solution nevertheless becomes difficult to implement when the distance separating two transistors or two gates decreases.

The document U.S. Pat. No. 10,134,901 B1 discloses another solution implemented in the production of a FinFET transistor. According to this solution, a fin-shaped channel based on a first semiconductor material is formed on a layer based on a second semiconductor material. After forming the channel and before epitaxy of the source and drain regions, an oxidation is carried out on the exposed surfaces of the first and second semiconductor materials. This allows forming an additional insulation portion in the layer based on a second semiconductor material, under the future source and drain regions. A selective deoxidation of the lateral surfaces of the channel is then performed, prior to a lateral epitaxy of the source and drain regions.

The drawback of this solution is that it requires the use of different materials for the substrate and for the channel, in order to carry out the selective deoxidation. Another drawback of this solution is that it requires a high number of steps.

An object of the present invention is to at least partially overcome some of the drawbacks mentioned above and to find an alternative to the solution described by the document U.S. Pat. No. 10,134,901 B1.

In particular, an object of the present invention is to propose an improved method of forming a source/drain region of a microelectronic device comprising an additional insulation portion.

Another object of the present invention is to propose a microelectronic device comprising a source/drain region limiting the leakage currents and/or reducing the access resistance at the contact.

The other objects, features and advantages of the present invention will appear on examining the following description and the accompanying drawings. It is understood that other advantages can be incorporated. In particular, some features and advantages of the method may be applied mutatis mutandis to the device, and vice versa.

### SUMMARY

In order to achieve this objective, a first aspect of the invention relates to a method for forming at least one source/drain region of at least one transistor, comprising the following steps:
Providing a bulk substrate carrying a transistor pattern,
   Said bulk substrate comprising:
A base portion made of a semiconductor material having an upper face extending in a basal plane and elongated along a longitudinal axis, and
First and second insulation portions located on either side of said base portion,
   Said transistor pattern comprising:
a channel surmounting the base portion and extending in particular along the longitudinal axis,
a transistor gate pattern transversely at least partially surrounding a central portion of the channel,
a spacer covering a flank of the gate pattern and transversely at least partially surrounding a lateral portion of the channel,
   the lateral portion of the channel and the spacer having respectively a facet and a flank extending transversely to the longitudinal axis,
Forming an additional insulation portion in the base portion, by oxidation of the semiconductor material from the upper face of the base portion,
Forming by selective epitaxy a source/drain region, mainly along the longitudinal axis, the source/drain region, in particular from said facet of the channel and preferably only from said facet of the channel,

Advantageously, the method being further comprises the following steps:
Before forming the additional insulation portion, forming a protective layer on the facet of the channel, said protective layer being configured to prevent an oxidation of the lateral portion of the channel when the additional insulation portion is formed by oxidation,
After forming the additional insulation portion and before forming the source/drain region, removing the protective layer.

Thus, the oxidation allowing forming the additional insulation portion does not change the lateral portion of the channel. The latter is protected by the protective layer during the formation of the additional insulation portion. It is therefore not necessary to provide a semiconductor material for the substrate which is different from the material of the channel. This allows releasing the constraints on the choice of the used semiconductor material(s).

Furthermore, it is not necessary to provide, upstream, a dimensional recess of the channel along the longitudinal axis, which occurs during the selective deoxidation taught by the known solutions. This simplifies the management of the steps of the method. The facet of the lateral portion of the channel is first covered by the protective layer, before forming the additional insulation portion, then uncovered after forming the additional insulation portion. This allows preserving this facet for the formation of the source/drain region.

The method according to the invention advantageously allows producing a FinFet transistor on a bulk substrate, by obtaining insulation performance similar to those obtained on a “semiconductor on insulator” type substrate, for example of the silicon on insulator (SOI) type. Such a standard SOI substrate typically costs about five times more expensive than a bulk substrate. The method according to the invention advantageously allows at least partially transforming a bulk substrate into a SOI type substrate, at a lower cost.

A second aspect of the invention relates to a microelectronic device comprising a transistor pattern supported by a substrate,

Said substrate comprising:
A base portion made of a semiconductor material having an upper face extending in a basal plane and elongated along a longitudinal axis, and
First and second insulation portions located on either side of said base portion,
   Said transistor pattern comprising:
at least one channel surmounting the base portion and extending mainly along the longitudinal axis,
a transistor gate pattern transversely surrounding a central portion of the at least one channel,
at least one spacer flanking the transistor gate pattern and transversely surrounding a lateral portion of the at least one channel,
a source/drain region extending from the lateral portion of the at least one channel,
   Said microelectronic device further comprising an additional insulation portion in the base portion, under the source/drain region.

Advantageously, the source/drain region of the microelectronic device has a frustoconical shape and is not in contact with the additional insulation portion. In particular, the source/drain region is not in direct electrical contact with the additional insulation portion, except possibly a basal portion of the source/drain region in close proximity to the lateral portion of the channel.

This allows increasing the distance separating the source/drain region from the base portion made of a semiconductor material. The electrical insulation of the source/drain region is improved. The leakage currents are decreased or even eliminated. This also allows forming a subsequent contact over an entire periphery of the source/drain region. Such a contact allows reducing the access resistance.

### BRIEF DESCRIPTION OF THE FIGURES

The aims, objects, as well as the features and advantages of the invention will become more apparent from the detailed description of an embodiment thereof which is illustrated by the following accompanying drawings in which:

FIGS. 1A to 1D schematically illustrate steps of forming a source/drain region of a FinFET transistor according to a method of the prior art.

FIGS. 2A to 21 schematically illustrate steps of forming a source/drain region of a microelectronic device according to one embodiment of the present invention.

FIG. 3 schematically illustrates a microelectronic device according to another embodiment of the present invention.

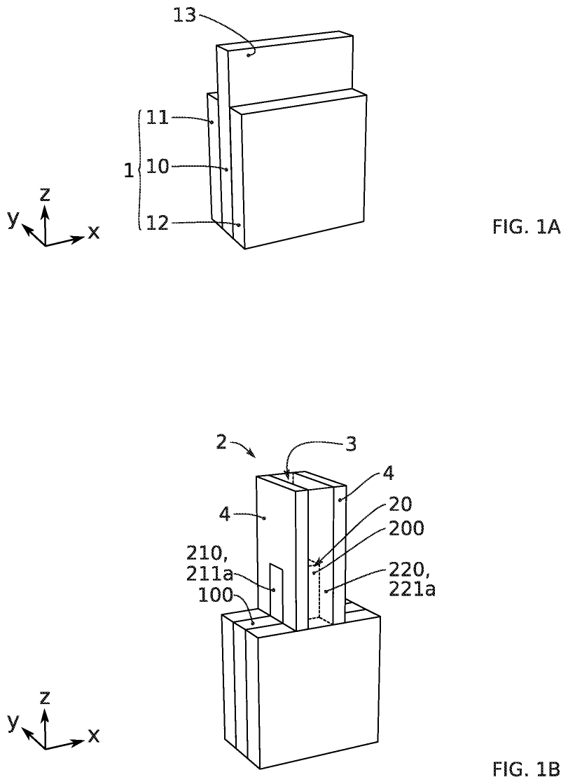

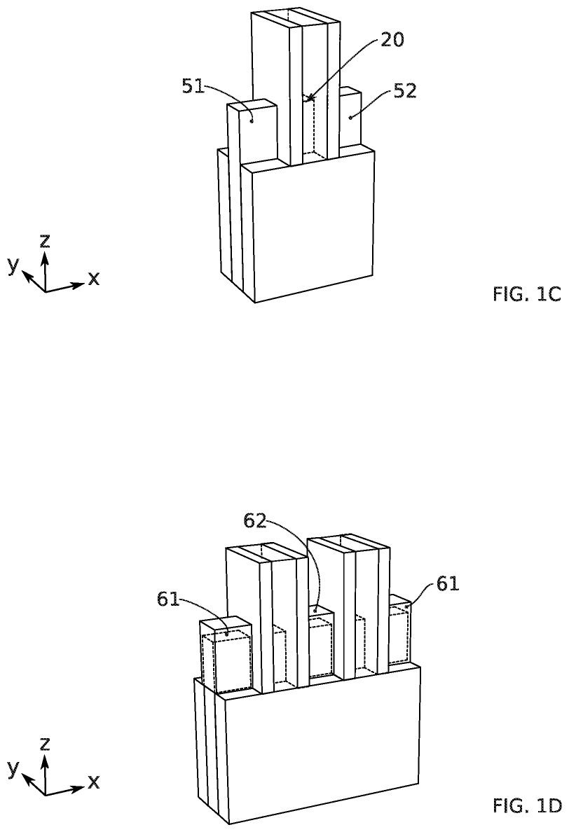

The drawings are given by way of example and are not limiting of the invention. They constitute schematic representations of principle intended to facilitate the understanding of the invention and are not necessarily on the scale of the practical applications. In particular, the relative dimensions of the different layers, portions and elements of the device (for example spacer, base portion, additional insulation portion, source/drain region, channel) are not representative of reality.

### DETAILED DESCRIPTION

Before starting a detailed review of embodiments of the invention, it is recalled that the invention, according to the first aspect thereof, comprises in particular the optional features below which can be used in combination or alternatively:

According to one example, the channel passes through the gate pattern and the spacers so as to have a free facet at each of the longitudinal ends thereof.

According to one example, the additional insulation portion extends below the protective layer. This allows preventing a base portion residue from remaining exposed when removing the protective layer.

According to one example, the method further comprises, after forming the additional insulation portion and before removing the protective layer, a thinning of the additional insulation portion in a direction normal to the basal plane. This allows compensating for an increase in volume during the formation of the additional insulation portion by oxidation. This allows obtaining an additional insulation portion having an upper face corresponding substantially to the upper face of the base portion before implementation of the method.

According to one example, the method further comprises, before forming the additional insulation portion and after forming the protective layer, a selective etching of the base portion relative to the first and second insulation portions and the protective layer. According to one example, said selective etching is configured to etch the semiconductor material of the base portion from the upper face at a depth comprised between 2 nm and 30 nm. Etching is herein prior to oxidation. This is an alternative to the thinning considered in the previous paragraph. Likewise, this allows compensating for an increase in volume during the formation of the additional insulation portion by oxidation. This allows obtaining an additional insulation portion having an upper face corresponding substantially to the upper face of the base portion before implementation of the method.

According to one example, the additional insulation portion extends beyond the protective layer, under the lateral portion of the channel. This further allows improving the insulation against leakage currents.

According to one example, the additional insulation portion extends under the entire channel. This allows further improving the insulation against leakage currents.

According to one example, the formation of the additional insulation portion is done by thermal oxidation, said thermal oxidation being configured to propagate mainly from the upper face along the longitudinal axis.

According to one example, at least one portion of the source/drain region formed by lateral epitaxy is not in contact with or does not bear on the additional insulation portion. Thus a space exists between the source/drain region formed by lateral epitaxy and the additional insulation portion. This space can be filled with a dielectric material during a subsequent phase of the method. Thus, the epitaxy is not performed from the additional insulation portion. There is no contact between the source/drain region and the additional insulation portion.

According to one example, the lateral epitaxy is configured so that the source/drain region is in contact with the additional insulation portion.

According to one example, the spacer is based on a first material A and the protective layer is based on a second material B different from the first material A.

According to one example, the removal of protective layer is done by selective etching of the second material B relative to the first material A, for example with an etching selectivity S_{B:A}>5:1.

According to one example, the first material A is different from the second material B.

According to one example, the first and second materials A and B are taken from a silicon nitride (SiₓN_{y}, x and y being non-zero integers) and a silicon boronitride SiBCN.

According to one example, the first material A is a silicon nitride (SiₓN_{y}, x and y being non-zero integers) and the material B is a silicon oxide (SiₓO_{y}, x and y being non-zero integers) or a silicon boronitride SiBCN.

According to one example, the method further comprises forming a metal contact around the source/drain region.

According to one example, the protective layer bears on the upper face of the base portion. It is in contact with the base portion. This allows protecting a facet of a channel which extends from the base region, in contact therewith.

According to one example, the facet and the flank extend substantially in the same plane, transverse to the longitudinal axis.

According to one example, the additional insulation portion has a height comprised between 2 nm and 40 nm.

According to one example, the source/drain region formed by lateral epitaxy has a frustoconical shape.

According to one example, the channel is based on the semiconductor material of the base portion of the substrate.

According to one example, the channel is in contact with the base portion and has a shape protruding from the basal plane, for example a fin shape, such that the at least one transistor is a fin geometry field effect transistor, called Fin FET.

According to one example, a plurality of channels is formed, each channel having:
a central portion at least partially surrounded by the transistor gate pattern, and
a lateral portion at least partially surrounded by the at least one spacer and having a facet extending transversely to the longitudinal axis,
a source/drain region being made by epitaxy from the facets of the plurality of channels.

According to one example, the transistor gate pattern completely surrounds the central portions of the channels of the plurality of channels, such that the at least one transistor comprises a plurality of gate-all-around transistors, called GAA.

The invention according to the second aspect thereof, comprises in particular the optional features below which can be used in combination or alternatively:

According to one example, the device further comprises a contact surrounding the source/drain region.

According to one example, the contact completely surrounds the source/drain region, around the longitudinal axis.

Unless incompatible, it is understood that the device and the method may comprise, mutatis mutandis, all optional features above.

In the present application, the terms “a” channel or “a” spacer mean “at least one” channel or “at least one” spacer.

It is specified that within the scope of the present invention, the terms “on”, “surmounts”, “covers” or “underlying” or the equivalents thereof do not necessarily mean “in contact with”. Thus, for example, a channel surmounting a base portion does not necessarily mean that the channel and the base portion are directly in contact with each other, but this means that the channel at least partially covers the base portion by being either directly in contact therewith or by being separated therefrom by at least one other layer or at least one other element.

A layer can also be composed of several sub-layers of the same material or of different materials.

The terms a substrate, a layer, a device, “based” on a material M, mean a substrate, a layer, a device comprising only this material M, or this material M and possibly other materials, for example alloying elements, impurities or doping elements. Thus, a spacer based on silicon nitride SiN can for example comprise non-stoichiometric silicon nitride (SiN), or stoichiometric silicon nitride (Si₃N₄), or else a silicon oxynitride (SiON).

In general, but without limitation, a spacer forms a ring around the gate, with a closed contour; the description of a spacer preferably means this single spacer around the gate; however, the cross-sectional illustration drawings, generally along a plane parallel to the longitudinal direction of the channel, show two spacer portions on either side of the flanks of the gate. By extension, these two spacer portions are often designated by “the spacers”. The latter terminology may possibly be adopted in this application. Moreover, the invention extends to the embodiments in which at least two discontinuous spacers cover a gate pattern.

The present invention allows in particular manufacturing at least one transistor or a plurality of transistors on a substrate. This substrate is preferably bulk. According to an alternative possibility, this substrate may be of the semiconductor on insulator type, for example a silicon on insulator SOI substrate or a germanium on insulator GeOI substrate. The base portion, and the first and second isolation regions are typically formed in a surface portion of the substrate, typically on the front face of the substrate.

The invention can also be implemented more broadly for different microelectronic devices or components.

The terms “component”, “device” or “microelectronic device element”, mean any type of element made with the means of microelectronics. These devices include in particular, in addition to purely electronic devices, micromechanical or electromechanical devices (MEMS, NEMS . . . ) as well as optical or optoelectronic devices (MOEMS . . . ).

Several embodiments of the invention implementing successive steps of the manufacturing method are described below. Unless explicitly stated, the adjective “successive” does not necessarily imply, although this is generally preferred, that the steps immediately follow each other, intermediate steps being able to separate them. Moreover, the term “step” means carrying out a portion of the method, and can designate a set of sub-steps.

The term “dielectric” describes a material whose electrical conductivity is low enough in the given application to be used as an insulator. In the present invention, a dielectric material preferably has a dielectric constant of less than 7. The spacers are typically formed of a dielectric material.

The terms “gate pattern”, “gate stack”, “gate” are used a synonyms.

The term “selective etching relative to” or “etching having selectivity relative to” mean an etching configured to remove a material A or a layer A relative to a material B or a layer B, and having an etching speed of the material A greater than the etching speed of the material B. The selectivity is the ratio between the etching speed of material A to the etching speed of the material

B.

In the present patent application, one will preferably speak of thickness for a layer, height for a device (transistor or gate for example) and depth for a cavity or an etching. The thickness is taken in a direction normal to the main extension plane of the layer, the height and depth are taken in a direction normal to the base plane of the substrate. The main extension plane of the layer, respectively the base plane of the substrate, is generally parallel to a lower face or an upper face of this layer, respectively of this substrate.

In the present patent application, a preferably orthonormal reference frame formed by the x, y, z axes is represented in the accompanying drawings. The substrate, more specifically the lower face thereof and/or the upper face thereof, extend in the basal xy plane.

In the following, the length is taken in the direction carried by the x axis, called longitudinal axis, the width is taken in the direction carried by the y axis.

An element located “in line with” or “perpendicular to” another element means that these two elements are both located on the same line perpendicular to the basal plane, that is to say on the same line oriented along the z axis in Figures.

The term “horizontal” means an orientation parallel to a xy plane. The term “vertical” means an orientation parallel to the z axis.

The terms “substantially”, “about”, “in the range of” mean “within 10%” or, in the case of an angular orientation, “within 10° ”. Thus, a direction substantially normal to a plane means a direction having an angle of 90±10° relative to the plane.

The invention will now be described in detail through a few non-limiting embodiments.

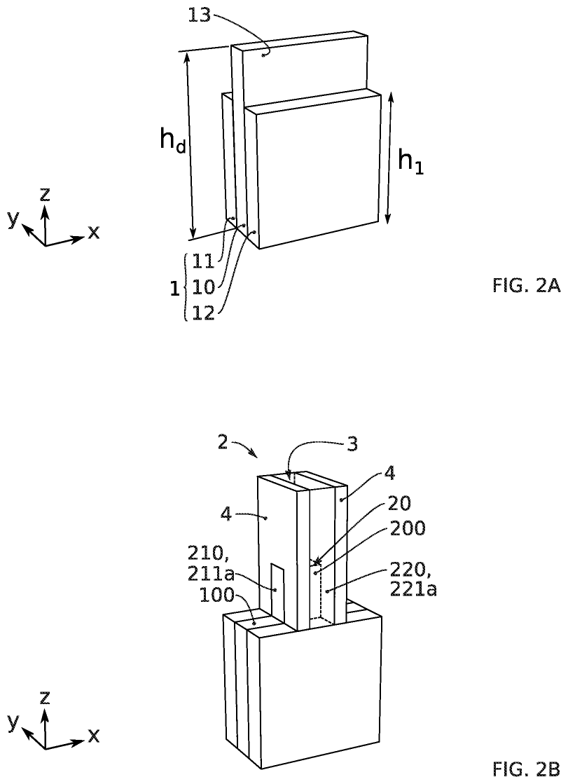

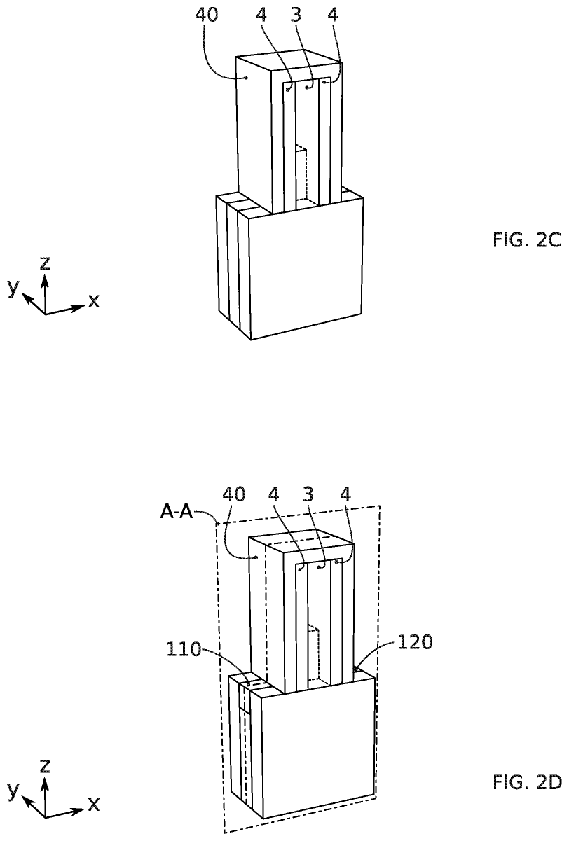

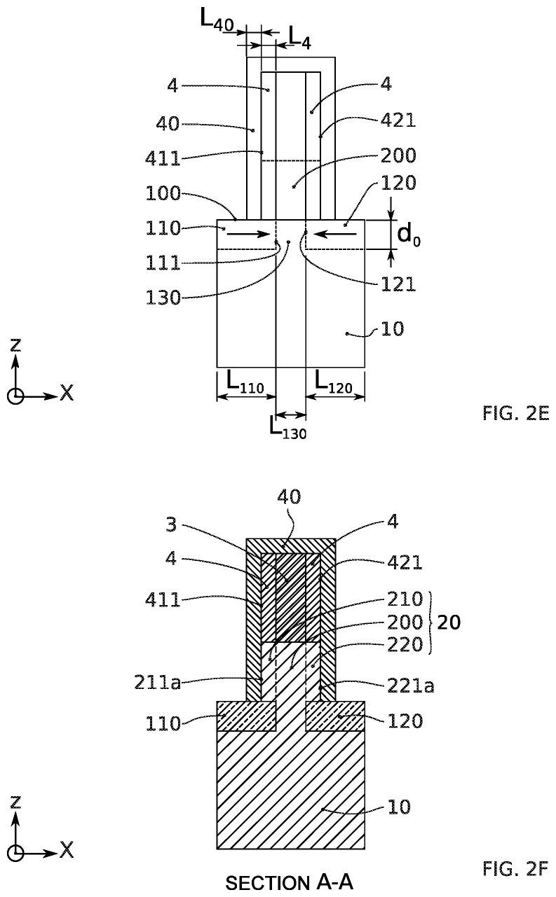

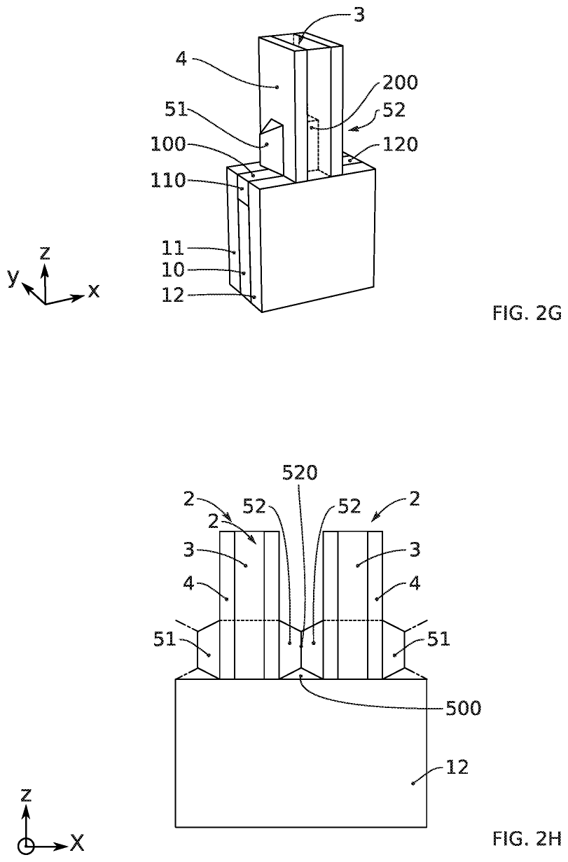

A first embodiment of the method is illustrated in FIGS. 2A-2H.

This method is preferably implemented on an initial structure comprising a substrate 1 and a fin 13, as illustrated in FIG. 2A for example.

Such a structure can typically be obtained from a bulk silicon substrate. In this case, the bulk substrate is etched at a depth h_{d} comprised between a few tens of nanometers and a few hundred nanometers, to form a thin silicon wall of height h_{d}. Insulation portions 11, 12 are then formed on either side of the thin wall, for example by depositing silicon oxide, over a height h₁<h_{d}. The portion of the thin wall located between the insulation portions 11, 12 is called base portion 10. The base portion 10 thus has a height h₁. The base portion 10, forms, with the insulation portions 11, 12, the substrate 1. The exposed faces of the insulation portions 11, 12, in the xy plane, thus define the basal plane of the substrate 1.

The portion of the thin wall which remained free, protruding from the basal plane and surmounting the base portion 10, is called fin 13. The fin 13 thus has a height h_{d}-h₁. The thin wall herein comprised the base portion 10 and the fin 13, as illustrated in FIG. 2A. The fin 13 typically has a longitudinal dimension L₂₀ along x in the range of several tens of nanometers, for example 10 nm L₂₀ 200 nm, and a transverse dimension W₂₀ along y in the range of a few nanometers, for example 5 nm W₂₀ 30 nm. The base portion 10 typically has a longitudinal dimension L₁₀ along x in the range of several tens of nanometers, for example 10 nm ≤L₁₀ ≤200 nm, and a transverse dimension W₁₀ along y in the range of a few nanometers, for example 5 nm ≤W₁₀ ≤30 nm. The longitudinal dimensions are preferably equal, i.e. L₁₀=L₂₀. The transverse dimensions can be equal, i.e. W₁₀=W₂₀. Alternatively, the transverse dimension W₂₀ of the fin 13 may vary along its height, typically it may decrease from the base of the fin 13 attached to the base portion 10, to the top of the fin 13. The fin 13 thus has a transverse section, in a plane normal to the longitudinal direction x, of pyramidal or frustoconical shape. The transverse dimension W₁₀ of the base portion 10 can vary along its height h₁. The base portion 10 can typically have a pyramidal or frustoconical transverse section.

According to another possibility, the thin wall can be based on silicon-germanium SiGe.

As illustrated in FIG. 2B, the fin 13 is then structured so as to form a channel 20 of a transistor pattern 2. This channel 20 typically comprises herein a central portion 200 and two lateral portions 210, 220 on either side of the central portion 200. A gate pattern 3 is typically formed astride the fin 13, so as to define the central portion 200 of the channel 20. In a known manner, this gate pattern 3 can be a functional gate such as implemented in “gate first” type methods (the gate is kept at the end of the completion of the spacers), or a sacrificial gate such as implemented in “gate last” type methods (the gate is replaced at the end of the completion of the spacers).

The gate pattern 3 extends mainly transversely to the longitudinal x axis. It can beat on the insulation portions 11, 12, on either side of the central portion 200 of the channel 20.

The gate pattern 3 is typically flanked by one or more spacer(s) 4. These spacers 4 are formed astride the fin 13, so as to define the lateral portions 210, 220 of the channel 20. The spacers 4 extend mainly transversely to the longitudinal axis x. They can rest on the insulation portions 11, 12, on either side of the lateral portions 210, 220 of the channel 20. The spacers 4 are preferably directly in contact with the gate pattern 3. They have a thickness L₄ along x, preferably approximately constant, and for example comprised between 2 nm and 10 nm. The spacers 4 are typically based on silicon nitride SiN or SiBCN or SiCO.

After formation of the gate pattern 3 and the spacers 4, the exposed portions of the fin 13 are etched, for example by anisotropic etching along z. This anisotropic etching is preferably configured to stop on an upper face 100 of the base portion 10. At the end of this anisotropic etching, the lateral portions 210, 220 have respectively exposed facets 211a, 221a. These facets 211a, 221a can extend substantially in the same yz plane as the flanks 411, 421 of the spacers 4. The channel 20 thus passes through the gate pattern 3 and the spacers 4 so as to have a free facet 211a, 221a at each of the longitudinal ends thereof.

The transistor pattern 2 herein comprises the gate pattern 3, the spacers 4, and the central 200 and lateral portions 210, 220 of the channel 20. The transistor pattern 2 can also comprise a hard mask on the gate pattern and the spacers, at the top of the transistor pattern (not illustrated). This transistor pattern 2 typically corresponds to a so-called “FinFET” transistor architecture. The transistor pattern 2 surmounts the substrate 1. An upper face 100 of the base portion 10 is exposed.

After structuring or providing the transistor pattern 2, a protective layer 40 is formed, as illustrated in FIG. 2C. This protective layer 40 preferably covers the flanks of the spacers 4, the top of the transistor pattern 2, and the facets 211a, 221a. This allows in particular protect the facets 211a, 221a during the subsequent oxidation step. The protective layer 40 has a thickness L₄₀ which is preferably approximately constant, and for example comprised between 1 nm and 10 nm. The protective layer 40 can typically be deposited in a conformal manner on the transistor pattern 2, for example by Atomic Layer Deposition (ALD) or chemical vapor deposition (CVD). It is then etched so as to expose a portion of the upper face 100 of the base portion 10. The protective layer 40 may be based on silicon boronitride SiBCN. According to another possibility, the protective layer 40 may be based on silicon oxide. The protective layer 40 is preferably made of a material different from the material of the spacers 4. This will then allow selectively removing the protective layer 40, without damaging the spacers 4.

FIG. 2D illustrates the formation of the additional insulation portions 110, 120 in the substrate 1, after forming the protective layer 40 on the transistor pattern 2. These additional insulation portions 110, 120 are preferably made by thermal oxidation of the semiconductor material of the base portion 10 of the substrate 1. In a known manner, the thermal oxidation can for example be carried out at a temperature comprised between 750 and 1050° C. The reader may refer to the document “The physics and chemistry of SiO2 and the Si-SiO2 interface, Helms and Deal, 1988” to determine the oxidation conditions, for example as taught on pages 17 to 23 of this document. This oxidation takes place from the exposed upper face 100 of the base portion 10. It propagates within the base portion 10 to form the additional insulation portions 110, 120 under the upper face 100. The upper face 100 becomes an upper face 100 of the additional insulation portions 110, 120.

As illustrated in FIG. 2E, the oxidation fronts 111, 121 also progress along x. Thus, the additional insulation portions 110, 120 can be formed under the protective layer 40, and preferably under the spacers 4. A part 130 of the base portion 10 can subsist substantially under the central portion 200 of the channel 20, between the additional insulation portions 110, 120. However, this part which subsists may be the source of leakage currents from the future source and drain regions towards the substrate. Thus, L₁₃₀ is preferably smaller than the distance, measured along the x axis, separating the flanks 411, 421 of the spacers 4, preferably L₁₃₀ is zero. According to one embodiment, L₁₃₀ is preferably smaller than the dimension, measured along the x axis, of the gate pattern 3.

The additional insulation portions 110, 120 thus formed preferably have a height d₀ corresponding to the oxidation depth, and respectively lengths L₁₁₀, L₁₂₀. The oxidation depth d₀ is preferably comprised between 2 nm and 20 nm. The lengths L₁₁₀, L₁₂₀ are preferably comprised between 10 nm and 100 nm. The part 130 may have a length L₁₃₀ comprised between 0 nm and 50 nm. In the case where the substrate carries densely distributed transistor patterns, the lengths L₁₁₀, L₁₂₀ may partially depend on the spacing between two adjacent transistor patterns.

As illustrated in FIG. 2F in section along the plane A-A′ represented in FIG. 2D, the additional insulation portions 110, 120 are preferably advanced under the lateral portions 210, 220 of the channel 20, and preferably under the central portion 200 of the channel 20.

According to another possibility, the oxidation fronts 111, 121 are joined together substantially under the central portion 200 of the channel, such that the channel 20 is completely isolated from the base portion 10. Thus, L₁₃₀=0. According to this preferred possibility, the additional insulation portions 110, 120 form a continuous portion under the channel. The oxidation conditions are chosen so that the length L₁₃₀ of the part 130 is as small as possible, and preferably so that the length L₁₃₀ of the part 130 is zero. This allows limiting or even eliminating the leakage currents from the source and drain regions towards the substrate.

A thinning of the additional insulation portions 110, 120 in the z direction is preferably performed. This allows compensating for an increase in volume during the formation of the additional insulation portions 110, 120 by oxidation. The thinning can be configured so that the additional insulation portions have an upper face corresponding substantially to the upper face 100 of the base portion 10 before oxidation. According to another possibility, the thinning can be continued so that the additional insulation portions have an upper face located under the upper face 100 of the base portion 10 before oxidation. This allows increasing the volume of the source/drain regions. This therefore allows reducing the resistance of access to the transistor. This thinning can be performed by anisotropic etching along z.

According to an alternative possibility or in combination with the thinning, the base portion 10 can be etched prior to the formation of the additional insulation portions 110, 120, so as to locally lower the level of the upper face 100. This allows taking into account the increase in volume due to oxidation, during the formation of the additional insulation portions 110, 120. This etching of the base portion 10 is typically selective relative to the insulation portions 11, 12. Thus, only the base portion 10 is etched. The insulation portions 11, 12 remain substantially unchanged. This etching of the base portion 10 can be done at a depth along z of a few nanometers to a few tens of nanometers, for example between 2 nm and 30 nm. The additional insulation portions 110, 120 can then be formed.

After forming the additional insulation portions 110, 120, the protective layer 40 is removed so as to again expose the facets 211a, 221a of the lateral portions 210, 220 of the channel. The removal of the protective layer 40 is preferably carried out by selective etching of the protective layer 40 relative to the spacers 4. This selective etching may have an etching selectivity S_{B:A} of the material B of the protective layer relative to the material A of the spacers, greater than 5:1. This selective etching also preferably has an etching selectivity S_{B:C} of the material B of the protective layer relative to the material C of the additional insulation portions, greater than 5:1. This selective etching also preferably has an etching selectivity S_{B:D} of the material B of the protective layer relative to the semiconductor material D of the lateral portions of the channel, greater than 5:1. The protective layer 40 is thus removed without damaging or without completely removing the spacers 4 and/or the additional insulation portions 110, 120 and/or the lateral portions 210, 220 of the channel 20.

As illustrated in FIG. 2G, after removing the protective layer 40, a method of selective epitaxy which is doped in situ is implemented to form the source/drain regions 51, 52 from the lateral portions 210, 220 of the channel 20. A boron (:B) or phosphorus (:P) doping can thus be obtained. The source/drain regions 51, 52 may for example be based on Si:P, Si:B or SiGe:B. This epitaxy of the source/drain regions 51, 52 takes place laterally from the exposed facets 211a, 221a. The epitaxial growth is thus initially mainly directed along x. The upper face 100 of the additional insulation portions 110, 120 avoids the epitaxial growth of the source/drain regions 51, 52 from the base portion 10.

According to one possibility, the source/drain regions 51, 52 are not in contact and/or do not bear on the upper face 100 of the additional insulation portions 110, 120. Thus a space or a non-zero distance exists between the source/drain region 51, 52 and the upper face 100 of the additional insulation portions 110, 120. This space can be filled with a dielectric material during a subsequent phase of the method.

The source/drain regions 51, 52 thus tend to adopt a frustoconical shape, as illustrated in FIG. 2G. In particular, the cross section of the source/drain regions 51, 52 decreases as they move away from the facets 211a, 221a. This transverse section of the source/drain regions 51, 52, taken in a transverse plane yz, may in particular have a regularly decreasing area. According to one possibility, only a negligible portion of the source/drain regions, located in the immediate vicinity of the facets 211a, 221a, is in contact with the upper face 100 of the additional insulation portions 110, 120. Such a negligible portion typically has a surface of contact with the lower upper face 100 of 20% of the projected surface of the source/drain regions 51, 52 on the upper face 100.

A clearance or a cavity 500 can thus be formed under the source/drain regions 51, 52, between the source/drain regions 51, 52 and the additional insulation portions 110, 120. This will then allow forming a coating contact surrounding at least one portion of the source/drain regions 51, 52, by filling this clearance or this cavity 500.

According to another possibility, this cavity 500 is filled with the epitaxy material from the source/drain regions 51, 52.

As illustrated in FIG. 2H, the substrate 1 can carry a plurality of adjacent transistor patterns 2. During the formation of the source/drain regions 51, 52 by lateral epitaxy, the source/drain regions 51, 52 resulting from two adjacent transistor patterns 2 can be joined together, for example at an interface 520 (FIG. 2H). In this example, the tops of two drains 52 are joined together at the interface 520 and a cavity 500 is formed under the drains 52. By prolonging the lateral epitaxy of the source/drain regions 51, 52 after they are fused, the cavity 500 can be filled with the epitaxy material of the source/drain regions 51, 52.

As illustrated in FIG. 21, contacts 61, 62 may then be formed around the source/drain regions 51, 52. These contacts are preferably formed so as to completely surround the source/drain regions 51, 52, preferably by filling the clearances and cavities 500. This allows increasing the contact surface between the contacts 61, 62 and respectively the source/drain regions 51, 52. This advantageously allows decreasing the access resistance at the contact. The contacts 61/62 can bear on the upper face 100 of the additional insulation portions 110, 120.

The method is thus particularly adapted for forming source/drain regions of FinFET transistors, as illustrated through this first embodiment. The method can also be implemented for other transistor architectures. The Si channel can thus be replaced by a Si/SiGe stack in the FinFET configuration.

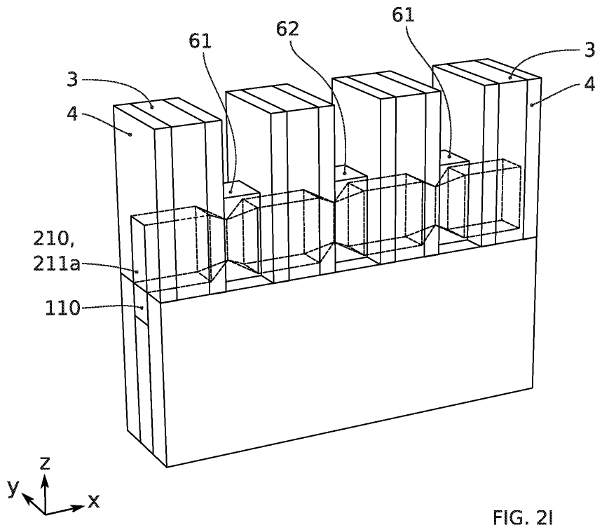

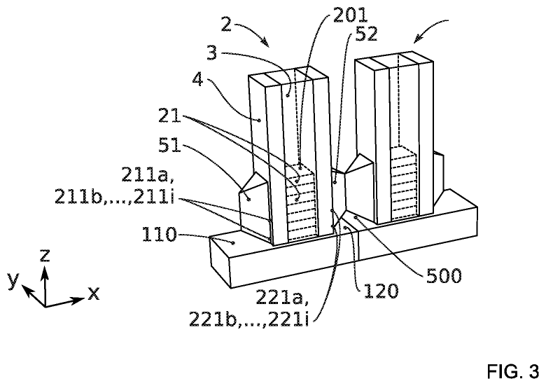

According to a second embodiment illustrated in FIGS. 3A, 3B, the method is implemented on “Gate All Around” GAA type transistors. In this embodiment, a stack of channels 21 is made instead of the channel 20 of the previous embodiment. Only the features different from the first embodiment are described below, the other features which are not described being deemed identical. Thus, prior to the deep etching of the bulk substrate allowing forming the thin wall, a stack of semiconductor layers alternating with sacrificial layers is formed on the bulk substrate.

This stack is then etched so as to form the portion of the thin wall protruding from the basal plane of the substrate. This protruding portion comprises the channels 21 resulting from the semiconductor layers, and separators resulting from the sacrificial layers. A sacrificial gate is then formed astride this protruding portion, at a central portion 201 of the protruding portion. Spacers 4 are formed as previously on either side of the sacrificial gate, at the lateral portions of the protruding portion.

An anisotropic etching then allows exposing facets 211a, 211b, . . . , 211i and 221a, 221b, . . . , 221i for each channel 21 of the protruding portion, as well as an upper face 100 in the basal plane of the substrate.

According to a principle of forming gate-all-around GAA transistors, the separators are typically removed then replaced in two steps. The separators are first partially removed at the lateral portions of the protruding portion. Cavities bordered by the spacers 4 are thus formed in the protruding portion. These cavities are then filled with a dielectric material, then erased by etching so as to form dielectric plugs at the ends of the separators.

At this stage, the transistor pattern 2 comprises the sacrificial gate, the spacers 4, the channels 21, the separators at the central portion 201 and the plugs at the lateral portions of the protruding portion.

A functional gate-all-around 3 is formed around the channels 21. When the separators are removed, the spacers 4 allow in particular supporting the channels 21. Such a transistor pattern 2 typically corresponds to a so-called “GAA” transistor architecture.

As previously, a protective layer can be deposited on the transistor pattern 2 thus formed. This protective layer may correspond to the deposition performed to form the plugs at the lateral portions of the protruding portion. The additional insulation portions 110, 120 can then be formed. The protective layer is then removed so as to expose the facets 211a-211i, 221a-221i. The source/drain regions 51, 52 are then formed by lateral epitaxy from the facets 211a-211i, 221a-221i. As a result, these source/drain regions have a frustoconical shape, defining a cavity 500 with the substrate. This allows increasing the dielectric barrier relative to the substrate and decreasing leakage currents. This then allows forming a coating contact on the source/drain regions 51, 52. Such a coating contact advantageously allows reducing the resistance of access to the source/drain regions 51, 52. This cavity 500 can also, for example, be filled with a dielectric material during a subsequent phase of the method.

The separators can then be removed at the central portion of the protruding portion. Conventionally, the sacrificial gate is removed, then the separators are removed and the method is thus particularly adapted for the formation of source/drain regions of GAA transistors. The present invention also relates to a device as described through the preceding exemplary embodiments.

The invention is not limited to the previously described embodiments and extends to all embodiments covered by the claims. The Si channel of the first embodiment can thus be replaced by a SiGe channel, or by a Si/SiGe stack in the FinFET configuration.

1. A method for forming at least one source/drain region of at least one transistor, comprising:
providing a bulk substrate carrying a transistor pattern,
said bulk substrate comprising:
a base portion made of a semiconductor material having an upper face extending in a basal plane and elongated along a longitudinal axis, and
first and second insulation portions located on either side of said base portion,
said transistor pattern comprising:
a channel surmounting the base portion and extending along the longitudinal axis,
a transistor gate pattern surrounding a central portion of the channel, the gate pattern having a flank, and
a spacer covering the flank of the gate pattern and transversely surrounding a lateral portion of the channel,
the lateral portion of the channel and the spacer having respectively a facet and a flank extending transversely to the longitudinal axis,
forming an additional insulation portion in the base portion, by oxidation of the semiconductor material from the upper face of the base portion, and
forming by selective epitaxy a source/drain region from said facet of the channel,
wherein the method further comprises:
before forming the additional insulation portion, forming a protective layer on the facet of the channel, said protective layer being configured to prevent an oxidation of the lateral portion of the channel when the additional insulation portion is formed by oxidation, and
after forming the additional insulation portion and before forming the source/drain region, removing the protective layer so as to expose the facet.

2. The method according to claim 1, wherein the additional insulation portion extends under the protective layer.

3. The method according to claim 1, further comprising, after forming the additional insulation portion and before removing the protective layer, thinning the additional insulation portion in a direction normal to the basal plane.

4. The method according to claim 1,
further comprising, before forming the additional insulation portion and after forming the protective layer, selective etching the base portion relative to the first and second insulation portions and the protective layer, said selective etching being configured to etch the semiconductor material of the base portion from the upper face at a depth comprised between 2 nm and 30 nm.

5. The method according to claim 1, wherein the additional insulation portion extends beyond the protective layer, under the lateral portion of the channel.

6. The method according to claim 1, wherein the additional insulation portion extends under the entire channel.

7. The method according to claim 1, wherein the formation of the additional insulation portion is done by thermal oxidation, said thermal oxidation being configured to propagate mainly from the upper face, mainly along the longitudinal axis.

8. The method according to claim 1, wherein at least one portion of the source/drain region formed by lateral epitaxy is not in contact with the additional insulation portion.

9. The method according to claim 1, wherein the lateral epitaxy is configured so that the source/drain region is in contact with the additional insulation portion.

10. The method according to claim 1, further comprising forming a metal contact surrounding the source/drain region.

11. The method according to claim 1, wherein the protective layer bears on the upper face of the base portion.

12. The method according to claim 1, wherein the facet and the flank extend substantially in the same plane, transverse to the longitudinal axis.

13. The method according to claim 1, wherein the source/drain region formed by selective epitaxy has a frustoconical shape.

14. The method according to claim 1, wherein the channel is in contact with the base portion and has a shape protruding from the basal plane, the shape being a fin shape, such that the at least one transistor is a fin geometry field effect transistor, called FinFET.

15. The method according to claim 1, wherein a plurality of channels is formed, each channel having:
a central portion at least partially surrounded by the transistor gate pattern, and
a lateral portion at least partially surrounded by the spacer and having a facet extending transversely to the longitudinal axis,
wherein a source/drain region is made by epitaxy from the facets of the plurality of channels.

16. The method according to claim 1, wherein the source/drain region is formed by selective epitaxy only from said facet of the channel.

17. A microelectronic device comprising a transistor pattern supported by a substrate,
said substrate comprising:
a base portion made of a semiconductor material having an upper face extending in a basal plane and elongated along a longitudinal axis, and
first and second insulation portions located on either side of said base portion,
said transistor pattern comprising:
at least one channel surmounting the base portion and extending mainly along the longitudinal axis,
a transistor gate pattern transversely surrounding a central portion of the at least one channel,
at least one spacer flanking the transistor gate pattern and transversely surrounding a lateral portion of the at least one channel, and
a source/drain region extending from the lateral portion of the at least one channel, and
said microelectronic device further comprising an additional insulation portion in the base portion, under the source/drain region.

18. The microelectronic device according to claim 17, wherein the source/drain region has a frustoconical shape.

19. The microelectronic device according to claim 17, wherein the source/drain region is not in contact with the additional insulation portion.
